(19) United States
(12) Patent Application Publication
(10) Pub. No.: US 2023/0413449 A1
(43) Pub. Date: Dec. 21, 2023

(54) METHOD FOR FABRICATING ELECTRONIC CIRCUIT AND METAL ION SOLUTION

(71) Applicant: National Tsing Hua University, Hsinchu City (TW)

(72) Inventors: Ming-Tsang Lee, Hsinchu City (TW); Yu-Bin Chen, Hsinchu City (TW); Swami Siddharth, Hsinchu City (TW)

(73) Assignee: National Tsing Hua University, Hsinchu City (TW)

(21) Appl. No.: 17/978,974

(22) Filed: Nov. 2, 2022

(30) Foreign Application Priority Data
Sep. 26, 2022 (TW) 111136317

(51) Int. Cl. H05K 3/02

(52) U.S. Cl. CPC H05K 3/02; H05K 2203/1194; H05K 2203/0789

(57) ABSTRACT

Provided is a method of fabricating an electronic circuit including providing a copper ion solution. The copper ion solution includes a source of copper (II) ions, L-ascorbic acid, and water. The copper ion solution is applied on a substrate to form a coating layer. A heat source is provided to locally heat the coating layer to react copper ions in the coating layer to form copper conductive patterns.

### CROSS-REFERENCE TO RELATED APPLICATION

This application claims the priority benefit of Taiwan application Ser. No. 111136317, filed on Sep. 26, 2022. The entirety of the above-mentioned patent application is hereby incorporated by reference herein and made a part of this specification.

### BACKGROUND

### Technical Field

The disclosure relates to a method for fabricating electronic circuit and a metal ion solution, and more particularly, to a method for fabricating electronic circuit and a copper ion solution.

### Description of Related Art

Printed circuit boards are widely used in electronic products. However, current printed circuit board fabrication processes are often highly contaminating. On the other hand, the slurry used in the fabrication or repair of the copper circuit of the circuit board usually has a surfactant and is in the form of particles, which limits the conductivity of the formed circuit and the compatibility of the process equipment. For example, metal particle slurry ink is not suitable for precision printing because metal particles tend to clog the print head nozzle.

### SUMMARY

The disclosure provides a metal ion solution that may be used with laser direct writing technology to fabricate conductive patterns/features with good electrical conductivity on a substrate.

A method of fabricating an electronic circuit according to an embodiment of the disclosure includes providing a copper ion solution. The copper ion solution includes a source of copper (II) ions, L-ascorbic acid, and water. The copper ion solution is applied on a substrate to form a coating layer. A heat source is provided to locally heat the coating layer to react copper ions in the coating layer to form copper conductive patterns.

The metal ion solution according to an embodiment of the disclosure is formed by a source of copper (II) ions, L-ascorbic acid, and water.

The environmental-friendly and particle-free copper ion reactive aqueous solution disclosed in the embodiment may be practically applied to a low-temperature process of a fine copper circuit for fine circuit fabrication or repair.

### BRIEF DESCRIPTION OF THE DRAWINGS

FIGS. 1 to 4 are schematic cross-sectional views of a method of fabricating an electronic circuit according to some embodiments of the disclosure.

FIG. 5 is an absorption spectrum of a copper ion solution at different time intervals according to experimental examples of the disclosure.

FIGS. 6A to 6E are optical microscope images of conductive patterns (fine copper line) according to experimental examples 1 to 5 of the disclosure.

FIG. 7 shows resistance values of conductive patterns (fine copper lines) formed by different numbers of scans according to experimental examples 1 to 5 of the disclosure.

### DESCRIPTION OF THE EMBODIMENTS

With traditional laser direct writing technology, after the ink including copper nanoparticles undergoes a soft baking process, almost all of the original copper nanoparticles turn into copper oxide nanoparticles. As a result, only poorly conductive copper oxide patterns/structures may be sintered.

The disclosure relates to a metal ion solution, and more particularly, to a particle-free metal ion solution that may be applied to flexible electronic products, circuit boards, low-temperature lamination manufacturing, and green manufacturing. The metal ion solution according to an embodiment of the disclosure includes a reducing agent and may be used to form metal patterns/features with excellent electrical conductivity. The metal ion solution disclosed in the embodiment may be practically applied to a low-temperature process of a fine metal circuit for fine circuit fabrication or repair.

The metal ion solution according to an embodiment of the disclosure includes a source of metal ions, L-ascorbic acid, and water. The source of metal ions is a source of copper (II) ions. The source of copper (II) ions may be copper acetate, copper formate, copper citrate, or a combination thereof. In some embodiments, the content of copper (II) ions of the copper ion solution is within the range of 0.2 mol/L to 0.55 mol/L.

As a reducing agent, L-ascorbic acid may can promote the reduction of metal ion to elemental metal. A content of the L-ascorbic acid in the solution is, for example, 0.5 mol/L to 1.7 mol/L. In some embodiments, the metal ion solution uses only L-ascorbic acid as a reducing agent, and does not include other reducing agents.

Water is used as a solvent. The water may be deionized water or pure water. In some embodiments, the metal ion solution uses only water as the solvent, and does not include other solvents. The water and L-ascorbic acid (vitamin C) of the metal ion solution of this embodiment are both environmentally friendly and biocompatible materials.

In some embodiments, an equivalent proportion of the L-ascorbic acid to copper (II) ions of the source of copper (II) ions is 2:1 to 2.2:1. In other embodiments, an equivalent proportion of the L-ascorbic acid to copper (II) ions of the source of copper (II) ions is 2.2:1 to 2.7:1. In yet another embodiments, an equivalent proportion of the L-ascorbic acid to copper (II) ions of the source of copper (II) ions is 2.7:1 to 3:1.

In some embodiments, the viscosity of the metal ion solution under room temperature conditions is about 1.1 cP to 3.1 cP. In other embodiments, the viscosity of the metal ion solution under room temperature conditions is about 3.1 cP to 5.1 cP. In yet another embodiment, the viscosity of the metal ion solution under room temperature conditions is about 5.1 cP to 6.3 cP. When the viscosity of the metal ion solution is lower than 1.1 cP, the problem of unevenness in the line caused by temperature and concentration gradient induced convection is easily occurred. When the viscosity of the metal ion solution is greater than 6.3 cP, the voids in the metal circuit cannot be easily filled.

In some embodiments, the metal ion solution is mainly formed by a source of copper (II) ions, L-ascorbic acid, and water. In other embodiments, the metal ion solution is formed by a source of copper (II) ions, L-ascorbic acid, and water, and no other components are included. In yet another embodiment, the metal ion solution is mainly formed by a source of copper (II) ions, L-ascorbic acid, and water. Formic acid is also added to enhance the stability of the copper ion solution. An equivalent proportion of the formic acid to copper (II) ions is, for example, 1.9:1 to 2.1:1. In an embodiment of the disclosure, the metal ion solution does not include other additives, such as surfactant, pH adjusters, polymers (e.g., polyvinylpyrrolidone, PVP) or combinations thereof.

The metal ion solution according to an embodiment of the disclosure may be induced by a heat source to reduce the ions to form the conductive patterns/features of the electronic circuit. The conductive patterns/features may be line, island, block, etc.

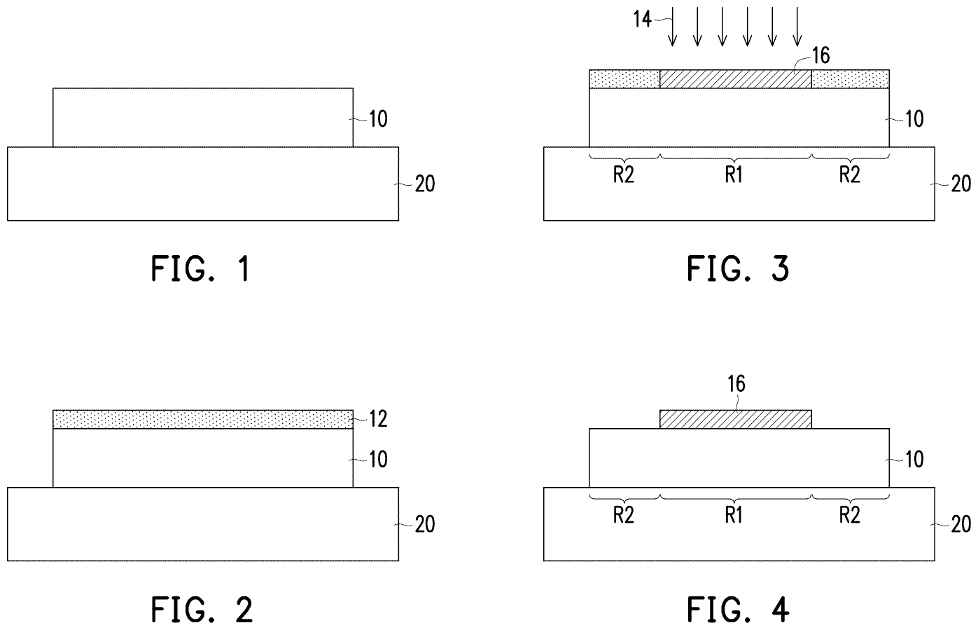

FIGS. 1 to 4 are schematic cross-sectional views of a method of fabricating an electronic circuit according to an embodiment of the disclosure.

Firstly, referring to FIG. 1, a substrate 10 is provided. The substrate 10 may be placed on a carrier 20. The carrier 20 may be fixed or movable. The substrate 10 may be a flexible substrate or a soft substrate. The Young's Module of the substrate 10 is, for example, 2000 to 4000 MPa. The material of substrate 10 has a low glass transition temperature. The glass transition temperature (Tg) of the material of the substrate 10 is, for example, 100° C. to 200° C. The material of the substrate 10 may be an organic material or a polymer, such as polyethylene terephthalate (PET), polydimethylsiloxane (PDMS), polyimide, poly (ethylene naphthalate) (PEN), or a combination thereof.

Next, referring to FIG. 2, the metal ion solution according to an embodiment of the disclosure is coated on the substrate 10 to form a coating layer 12. The coating layer 12 may also be called a liquid film. The thickness of the coating layer 12 is, for example, 100 μm to 10 mm, but not limited thereto. In some embodiments, the coating layer 12 may cover the substrate 10 completely. In other embodiment, the coating layer 12 may partially cover the substrate 10, so that part of the surface of the substrate 10 is exposed.

After that, referring to FIG. 3, a heat source 14 is selectively provided to the coating layer 12 in a zone R1 of a base 10 to induce the reduction of the metal ion in the coating layer 12 by the heat source 14 to form conductive patterns/features 16. The heat source 14 is not provided to the coating layer 12 located in a zone R2 of the base 10. Therefore, the coating layer 12 located in the zone R2 does not undergo a reduction reaction and thus does not form conductive patterns/features.

The heat source 14 of the disclosure may be a direct writing laser beam, an ion beam, a xenon lamp, an arc, or a combination thereof, but not limited thereto. The wavelength range of the laser beam may be from 200 nm to 12 μm. The laser beam may be, for example, in the wavelength range of visible light, carbon dioxide, ultraviolet light, or infrared light. However, the wavelength range of the laser beam is not limited thereto, but depends on the wavelength at which the light can be effectively absorbed by the coating layer 12 or by the substrate 10. For example, an argon laser beam, a diode laser beam, or an Nd:YAG laser may be used. In some experimental examples, the reduction reaction of copper (II) ions in the coating layer 12 may be induced by laser scanning, and then fine copper line (conductive patterns/features 16) is formed on the surface of the substrate 10. Since the coating layer 12 on the zone R2 of the substrate 10 is not irradiated by the heat source 14, the copper (II) ion in the coating layer 12 does not react.

When directly writing the coating layer 12 with the heat source 14, the conductive patterns/features 16 may be formed on the substrate 10 either by moving the carrier 20 or moving the heat source 14. The movement of the aforementioned carrier 20 may be performed by, for example (but not limited to), using a pre-written LabVIEW (laboratory virtual instrumentation engineering workbench) program, which enables the computer to precisely control, for example (but not limited to), a servo motor to drive the movement of the carrier 20, and control the path and moving speed. On the other hand, the movement of the aforementioned heat source 14 may be achieved by scanning devices such as (but not limited to) programmable two-dimensional micromirror arrays scanner. In addition, depending on actual requirements, the line width and thickness of the conductive patterns/features may be controlled by controlling the heat source 14, such as the focusing diameter of the laser beam, scanning power, scanning speed, number of scans, and other variables.

Thereafter, referring to FIG. 4, the unreacted coating layer 12 on the zone R2 of the substrate 10 is removed. This may be done, for example, by cleaning the substrate 10. When cleaning, first use the deionized water to rinse the surface of the substrate 10 to remove the unreacted coating layer 12 and then rinsing with a volatile solvent, such as ethanol or acetone, to leave conductive patterns/features 16 on the substrate 20. The line width of the formed conductive patterns/features 16 is, for example, 80 micrometers to 100 micrometers. The resistance value of the formed conductive patterns/features 16 is 4 Ω or less, for example, 0.96 Ω to 3.7 Ω.

In order to further improve the adhesion of the elemental metal of the conductive patterns/features 16 to the surface of the substrate 10, the substrate 10 may undergo a surface treatment before being contacted with the metal ion aqueous solution. For example (but not limited to), cleaning the surface of the substrate 10 with methanol, ethanol, isopropanol, acetone, deionized water (DI water), and other solvents, and then treating with 10 W to 20 W oxygen plasma (oxygen plasma) for about 5 to 10 seconds. The type of solvent used for cleaning the substrate 10 surface is not particularly limited, as long as the oil and dirt on the substrate 10 surface are removed.

In order to help understand the disclosure, the disclosure is further described below through specific experimental examples, but the following experimental examples are only examples of the disclosure, and the protection scope of the disclosure is not limited to the following experimental examples.

### Experimental Examples 1 to 5

### Preparation of Copper Metal Ion Solution

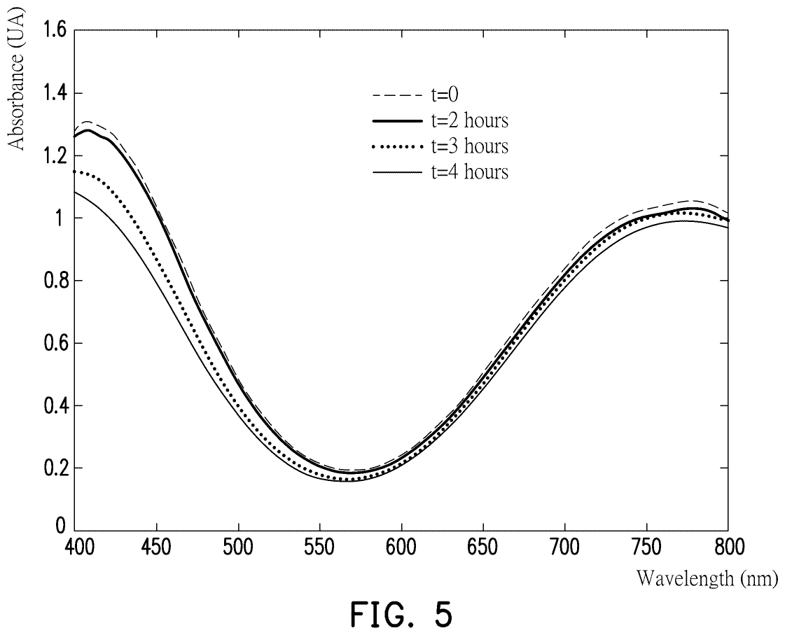

The preparation of the copper ion solution is divided into three steps. In the first step, 3 g of L-ascorbic acid (Honeywell, 99.9%) was added to 5 mL of 90° C. deionized water, and stirred to form an L-ascorbic acid aqueous solution. Ascorbic acid is also known as vitamin C. The solution was heated to 90° C. during mixing to accelerate the dissolution of the solute. Afterwards, the resulting viscous and transparent aqueous solution was cooled to room temperature. In the second step, 1 g of cupric acetate monohydrate (JT Baker, 99%) was added to 5 mL of deionized water, and the mixture was stirred at room temperature. Next, 0.4 mL of formic acid (JT Baker, 88%) was added dropwise. A small amount of formic acid was added to enhance the dissolution of copper and the stability of copper solution. In the third step, the L-ascorbic acid solution and the cupric acetate solution were mixed in a volume ratio of 1:1, and the mixture was filtered with a 220 nm syringe filter to remove the solid cluster by-products. The ion solution after vacuum drying at room temperature was examined by SEM and no nanomaterial was present. The absorption spectra of the solution were measured at different time intervals using an ultraviolet-visible spectrometer (Shimadzu, UV-2600i) to confirm the stability of the solution, and the resulting absorption spectra are shown in FIG. 5.

According to the results shown in FIG. 5, the copper (II) ion solution may be kept stable for at least 4 hours.

### Fabrication of Conductive Patterns/Features

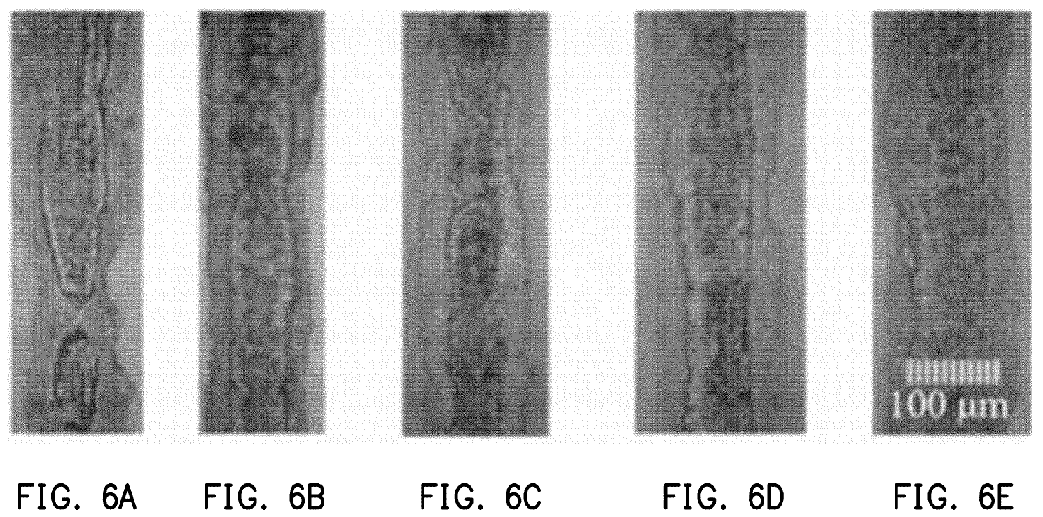

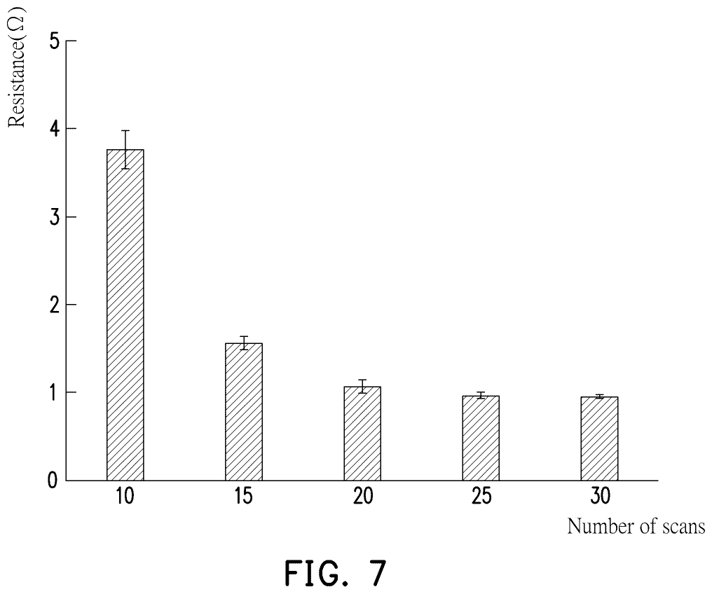

A PET film with a thickness of 100 μm and an area of 3 cm×3 cm was used as the substrate. The substrate was rinsed with deionized water, acetone, and isopropanol in sequence, and then the substrate was treated by using an atmospheric pressure plasma cleaner (model APPC103C, available from Solar Energy Tech. Inc., output voltage 10,000 to 50,000V, output frequency 4 to 5 MHz) with oxygen plasma for 5 seconds to improve the metal adhesion on the substrate surface. The substrate was fixed on a sample holder and its surface was kept flat. The prepared metal ion solution was dropped on the substrate surface using a pipet to form a layer of liquid film. Focused elliptical laser beam (continuous wave (CW) diode laser (Oxxius, ACX-HTSK)) with a wavelength of 640 nm and dimensions of 22 μm (semi-minor axis) and 240 μm (semi-major axis) was then irradiated to the ion solution liquid film using a. Scanning was carried out repeatedly at 550 mW laser power and 1 mm/s speed for 10, 15, 20, 25, and 30 times, respectively (experimental examples 1 to 5). Finally, the substrate was cleaned with deionized water and acetone to form conductive patterns/features (fine copper line) with a length of 15 mm and a line width of 100 μm on the substrate surface. Optical microscope images of experimental examples 1 to 5 are shown in FIGS. 6A to 6E. In addition, a micro resistance meter (available from Hioki, model RM3544-01, range 30 mΩ to 3MΩ, accuracy ±0.02%) was used to measure the resistance values of the conductive patterns/features of experimental examples 1 to 5. The results are shown in Table 1 and FIG. 7.

TABLE 1

| | Experi- | Experi- | Experi- | Experi- | Experi- |
|---|---|---|---|---|---|
| | mental | mental | mental | mental | mental |
| | example | example | example | example | example |
| | 1 | 2 | 3 | 4 | 5 |
| Number of scans | 10 | 15 | 20 | 25 | 30 |
| Average resistance | 3.76 | 1.56 | 1.06 | 0.97 | 0.96 |
| value (Ω) | | | | | |
| Length (mm) | 15 | 15 | 15 | 15 | 15 |
| Width (μm) | 80 | 90 | 95 | 100 | 100 |

The resistance values in Table 1 are the average of five samples and is marked with standard deviations as shown in FIG. 7. The results in Table 1 and FIG. 7 show that when the number of scans increased from 10 to 20, the resistance of the fine copper line decreased by 71%. When the number of scans increased from 20 to 30, the resistance of the fine copper line decreased by another 9%. Using a 3D-surface profiler, it was confirmed that the main reason for this phenomenon is that the thickness of the fine copper line increases significantly with the number of scans up to 20 times, and after 20 times, the thickness remains almost unchanged.

According to the above experimental examples, the resistivity of the fine copper line fabricated by laser scanning as the heat source may be as low as 4.7 μΩ cm after adjusting the laser parameters, which is very close to the resistivity of bulk copper metal (1.7 μΩ cm).

The metal ion solution of the disclosed embodiment includes environmental friendly biocompatible materials (water, L-ascorbic acid, etc.). The fine copper line may be fabricated by laser direct synthesis and patterning process. Moreover, since this metal ion solution is particle-free, nanomaterial agglomeration and inkjet nozzle clogging that occur in laser-induced metal oxide reduction and other similar techniques, may be prevented.

The metal ion solution of the disclosure may be successfully applied to fabricate conductive patterns/features. The method of using metal ion solution to fabricate conductive structures described in the disclosure may not only retain the advantages of traditional laser direct writing technology, but also further simplify the process to shorten the fabrication time. In addition, since the method of the disclosure may use flexible polymer as a substrate, it may can also be used to fabricate flexible electronic components which has a wide range of applications.

What is claimed is:

1. A method of fabricating an electronic circuit, comprising:
providing a copper ion solution mainly formed by the following components:
a source of copper (II) ions;
L-ascorbic acid; and
water;
applying the copper ion solution on a substrate to form a coating layer; and
providing a heat source to locally heat the coating layer to react copper ions in the coating layer to form a plurality of copper conductive patterns.

2. The method of fabricating an electronic circuit according to claim 1, further comprising removing an unreacted portion of the coating layer.

3. The method of fabricating an electronic circuit according to claim 1, wherein the heat source comprises a laser beam, an ion beam, a xenon lamp, an arc, or a combination thereof.

4. The method of fabricating an electronic circuit according to claim 1, wherein the copper ion solution does not comprise copper metal particles.

5. The method of fabricating an electronic circuit according to claim 1, wherein the substrate comprises a flexible substrate.

6. The method of fabricating an electronic circuit according to claim 1, wherein the source of copper (II) ions comprises copper acetate, copper formate, copper citrate, or a combination thereof.

7. The method of fabricating an electronic circuit according to claim 1, wherein a content of the source of copper (II) ions in the copper ion solution is 0.2 mol/L to 0.55 mol/L.

8. The method of fabricating an electronic circuit according to claim 1, wherein a content of the L-ascorbic acid in the copper ion solution is 0.5 mol/L to 1.7 mol/L.

9. The method of fabricating an electronic circuit according to claim 1, wherein an equivalent proportion of the L-ascorbic acid to copper (II) ions of the source of copper (II) ions is 2:1 to 3:1.

10. The method of fabricating an electronic circuit according to claim 1, wherein a resistivity value of the copper conductive patterns is 10 μΩ cm or less.

11. The method of fabricating an electronic circuit according to claim 1, wherein a surface roughness of the copper conductive patterns is 100 nm to 1000 nm.

12. A metal ion solution mainly formed by the following components:
a source of copper (II) ions;
L-ascorbic acid; and
water.

13. The metal ion solution according to claim 12, wherein a content of the source of copper (II) ions is 0.2 mol/L to 0.55 mol/L, and a content of the L-ascorbic acid is 0.5 mol/L to 1.7 mol/L.

14. The metal ion solution according to claim 12, wherein an equivalent proportion of the L-ascorbic acid to copper (II) ions of the source of copper (II) ions is 2:1 to 3:1.

15. The metal ion solution according to claim 12, wherein the source of copper (II) ions comprises copper acetate, copper formate, copper citrate, or a combination thereof.

16. The metal ion solution according to claim 12, wherein the metal ion solution does not comprise metal particles.

17. The metal ion solution according to claim 12, wherein the L-ascorbic acid is a reducing agent, and the metal ion solution does not comprise other reducing agents.
